(19) United States
(12) Patent Application Publication
(10) Pub. No.: US 2025/0085622 A1
(43) Pub. Date: Mar. 13, 2025

(54) Extreme Ultraviolet (EUV) Mask and Method of Fabrication Thereof

(71) Applicant: Taiwan Semiconductor Manufacturing Company, Ltd., Hsin-Chu (TW)

(72) Inventors: Chun-Lang CHEN, Tainan County (TW); Chung-Yang HUANG, Chiayi County (TW); Shih-Hao YANG, Tainan City (TW); Chien-Yun HUANG, Kaohsiung City (TW); Wei-Ting CHEN, Tainan City (TW)

(21) Appl. No.: 18/415,986

(22) Filed: Jan. 18, 2024

Related U.S. Application Data
(60) Provisional application No. 63/581,415, filed on Sep. 8, 2023.

(51) Int. Cl. G03F 1/24

(52) U.S. Cl. CPC G03F 1/24

(57) ABSTRACT

EUV masks and methods of fabrication thereof are described herein. An exemplary method includes receiving an EUV mask having a multilayer structure, a capping layer disposed over the multilayer structure, a patterned absorber layer disposed over the capping layer, and a patterned hard mask disposed over the patterned absorber layer. The method further includes removing the patterned hard mask by performing a first etching process to partially remove the patterned hard mask and performing a second etching process to remove a remainder of the patterned hard mask. The first etching process uses a first etchant, and the second etching process uses a second etchant. The second etchant is different than the first etchant. In some embodiments, the first etchant is a halogen-based plasma (e.g., a Cl₂ plasma), and the second etchant is a halogen-and-oxygen-based plasma (e.g., a Cl₂+O₂ plasma).

This is a non-provisional application of and claims benefit of U.S. Provisional Patent Application Ser. No. 63/581,415, filed Sep. 8, 2023, the entire disclosure of which is incorporated herein by reference.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. These goals have been achieved in large part by reducing IC dimensions (for example, minimum IC feature size), thereby improving production efficiency and lowering associated costs. However, such scaling has also increased complexity of the IC manufacturing processes. Similar advances in IC manufacturing are thus needed, such as higher resolution lithography processes, to realize continued advances in ICs and/or semiconductor devices and their performance.

Lithography processes used during IC and/or semiconductor manufacturing may use lithographic templates (e.g., photomasks, masks, reticles, etc.) to optically transfer patterns onto a material layer, which may be a portion of a substrate. Such a process may be accomplished, for example, by projecting a radiation source, through an intervening photomask or reticle, onto the material layer having a photosensitive material (e.g., photoresist) coating thereon. A minimum feature size that may be patterned by way of such a lithography process is limited by a wavelength of the projected radiation source. In view of this, extreme ultraviolet (EUV) radiation sources and EUV lithographic processes, including EUV photomasks (“masks”), have been introduced to pattern ever smaller device features. EUV masks may degrade with usage, resulting in poor pattern transfer that can result in device and/or circuit degradation or failure, and a speed of such EUV degradation may be impacted by fabrication of the EUV masks, such as an amount of oxygen introduced into the EUV masks during fabrication thereof. Although existing EUV masks and methods of fabrication thereof have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method, in portion or entirety, for fabricating an extreme ultraviolet (EUV) mask according to various aspects of the present disclosure.

FIGS. 2A-2E are cross-sectional views of an EUV mask, in portion or entirety, at various stages of the method of FIG. 1 according to various aspects of the present disclosure.

FIG. 3 is a cross-sectional view of an EUV mask, in portion or entirety, that may also be fabricated the method of FIG. 1 according to various aspects of the present disclosure.

FIG. 4 is a cross-sectional view of an EUV mask, in portion or entirety, that may also be fabricated the method of FIG. 1 according to various aspects of the present disclosure.

FIG. 5 is a schematic view of a lithography system, in portion or entirety, that may implement an EUV mask fabricated by the method of FIG. 1, such as the EUV masks of FIG. 2E, FIG. 3, and FIG. 4, according to various aspects of the present disclosure.

FIG. 6 is a flow chart of a method, in portion or entirety, for fabricating an EUV mask, such as by the method of FIG. 1, and using the EUV mask, such as the EUV masks of FIG. 2E, FIG. 3, and FIG. 4, according to various aspects of the present disclosure.

FIG. 7 is a flow chart of a method, in portion or entirety, for fabricating a semiconductor device and/or an IC using an EUV mask, such as the EUV masks of FIG. 2E, FIG. 3, and FIG. 4, according to various aspects of the present disclosure.

FIGS. 8A-8E are cross-sectional views of a workpiece, in portion or entirety, at various stages of the method of FIG. 7, according to various aspects of the present disclosure.

### DETAILED DESCRIPTION

The present disclosure relates generally to lithography, and more particularly, to extreme ultraviolet (EUV) lithography, EUV masks, and fabrication of EUV masks.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

Lithography processes used during integrated circuit (IC) and/or semiconductor manufacturing may use lithographic templates (e.g., photomasks, masks, reticles, etc.) to optically transfer patterns onto a material layer, which may be a portion of a substrate. Such a process may be accomplished, for example, by projecting a radiation source, through an intervening photomask or reticle, onto the material layer having a photosensitive material coating thereon. A minimum feature size that may be patterned by way of such a lithography process is limited by a wavelength of the projected radiation source. In view of this, extreme ultraviolet (EUV) radiation sources and EUV lithographic processes, including EUV photomasks (“masks”), have been introduced. Conventional EUV mask fabrication techniques introduce an amount of oxygen into EUV masks that increases their degradation and reduces their lifetime.

The present disclosure provides an EUV mask fabrication technique that minimizes an amount of oxygen in an EUV mask, which reduces degradation thereof and increases its lifetime. The EUV mask fabrication technique described herein implements a two-step etching process to remove a patterned hard mask used for patterning a layer of the EUV mask, such as an absorber layer thereof. The two-step etching process includes a halogen-based etch followed by a halogen-and-oxygen based etch. The halogen-based etch partially removes the patterned hard mask, and the halogen-and-oxygen based etch removes a remainder of the patterned hard mask. The two-step etching process may switch from the halogen-based etch to the halogen-and-oxygen based etch when a thickness of the patterned hard mask is reduced by the halogen-based etch to a predetermined percentage (e.g., about 30% to about 50%) of its original thickness. The two-step etching process reduces exposure of the EUV mask to oxygen, which may reduce oxidation of the EUV mask and/or reduce diffusion of oxygen into the EUV mask. For example, an atomic ratio of oxygen in an exposed portion of a capping layer of the EUV mask may be confined to less than about 10% using the disclosed two-step etching process. The two-step etching process may thus reduce an oxygen content in the EUV mask, thereby reducing degradation of an EUV mask and improving its lifetime. Different embodiments may have different advantages, and no particular advantage is required of any embodiment.

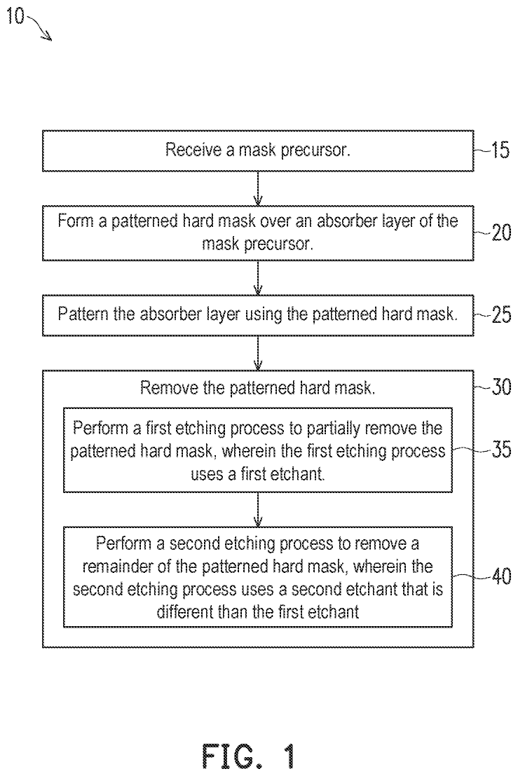

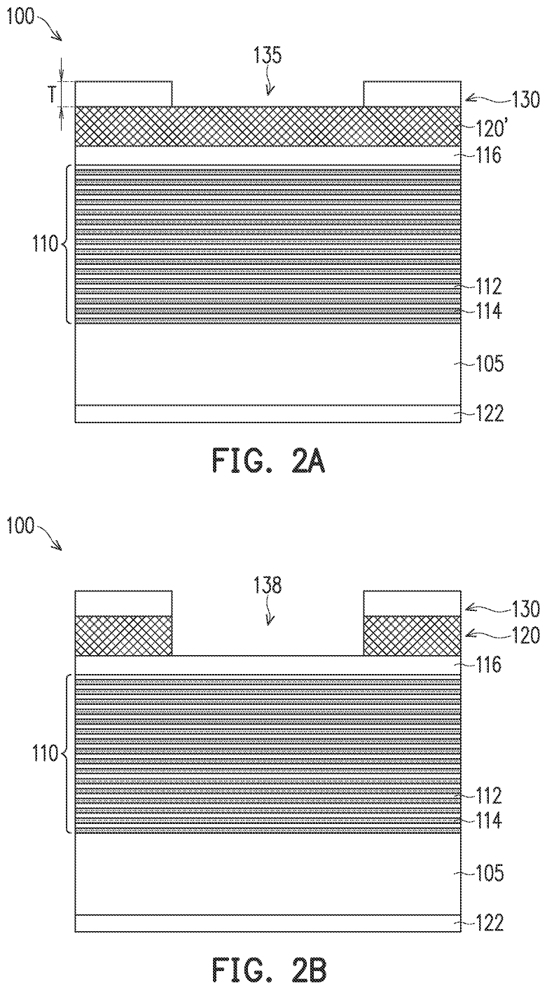

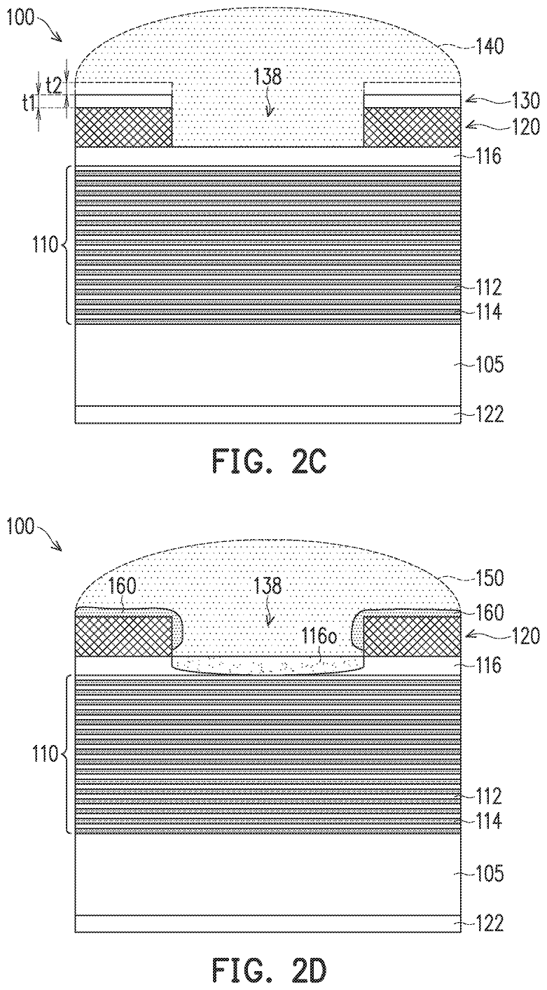

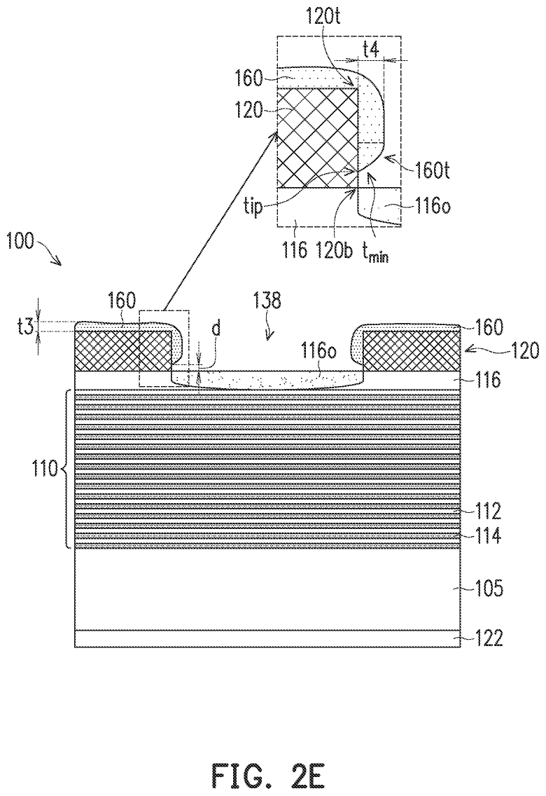

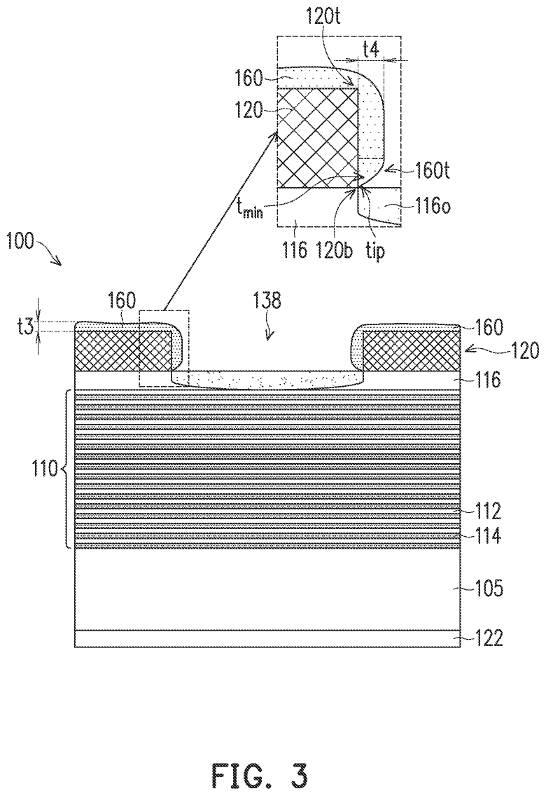

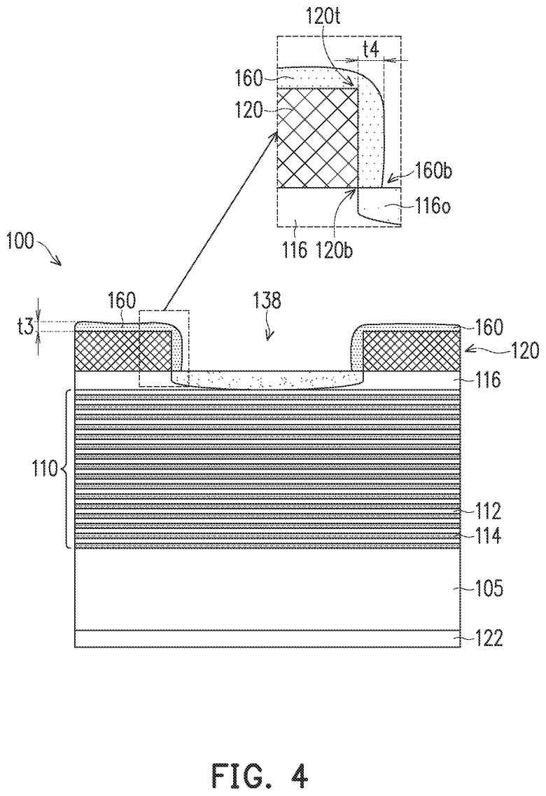

FIG. 1 is a flow chart of a method 10, in portion or entirety, for fabricating an extreme ultraviolet (EUV) mask according to various aspects of the present disclosure. FIGS. 2A-2E are cross-sectional views of an EUV mask 100, in portion or entirety, at various fabrication stages associated with method 10 of FIG. 1, according to various aspects of the present disclosure. FIG. 3 and FIG. 4 are cross-sectional views of EUV mask 100 having different configurations than the configuration depicted in FIG. 2E, which may also be fabricated by method 10 of FIG. 1, according to various aspects of the present disclosure. FIG. 1, FIGS. 2A-2E, FIG. 3, and FIG. 4 are discussed concurrently herein for ease of description and understanding. FIG. 1, FIGS. 2A-2E, FIG. 3, and FIG. 4 have been simplified for the sake of clarity to better understand the inventive concepts of the present disclosure. Additional steps may be provided before, during, and after method 10 of FIG. 1, and some of the steps described may be moved, replaced, or eliminated for additional embodiments of method 10 of FIG. 1. Additional features may be added in EUV mask 100, and some of the features described below may be replaced, modified, or eliminated in other embodiments of EUV mask 100.

Referring to FIG. 1 and FIG. 2A, method 10 at block 15 includes receiving a mask precursor for fabricating EUV mask 100. The mask precursor may include a substrate 105, a multilayer (ML) structure 110 (including, for example, reflective layers 112 and reflective layers 114), a capping layer 116, and an absorber layer 120′.

Substrate 105 may be a low thermal expansion material (LTEM) substrate, which may be formed of quartz, low thermal expansion glass, silicon, silicon carbide, silicon oxide, titanium oxide, other low thermal expansion material, or a combination thereof (e.g., TiO₂ doped SiO₂). In some embodiments, the LTEM substrate is a low thermal expansion glass substrate, such as a fused silica substrate. In some embodiments, the LTEM substrate is a quartz substrate. In some embodiments, the LTEM substrate is a fused quartz substrate.

ML structure 110 (also referred to as a reflective ML or a reflective ML coating) is disposed over substrate 105. ML structure 110 is configured to provide a reflectivity to a given radiation type/wavelength. For example, ML structure 110 is configured to reflect EUV radiation. ML structure 110 includes a stack of pairs of reflective layers, each of which may include a respective reflective layer 112 and a respective reflective layer 114. In some embodiments, reflective layers 112 are molybdenum (Mo) layers, reflective layers 114 are silicon (Si) layers, and ML structure 110 includes a stack of molybdenum-silicon (Mo/Si) film pairs. In some embodiments, reflective layers 112 are molybdenum (Mo) layers, reflective layers 114 are beryllium (Be) layers, and ML structure 110 includes a stack of molybdenum-beryllium (Mo/Be) film pairs. In some embodiments, ML structure includes a stack of other material layer pairs. A number of reflective layers, thicknesses of the reflective layers, and materials of the reflective layers are selected to provide ML structure 110 with a desired reflectivity based on intended exposure radiation and its properties, such as wavelength and/or angle of incidence thereof. In some embodiments, ML structure 110 includes twenty to eighty Mo/Si pairs (e.g., 40 pairs). In some embodiments, ML structure 110 is a multilayer mirror (MLM) configured to reflect incident radiation, such as EUV radiation.

Capping layer 116 is disposed over ML structure 110. Capping layer 116 may function as an etch stop when absorber layer 120′ is patterned by an etching process, and capping layer 116 may protect ML structure 110 during fabrication of EUV mask 100 (e.g., capping layer 116 may prevent and/or reduce oxidation of ML structure 110). In some embodiments, capping layer 116 includes ruthenium (Ru), niobium (Nb), rhodium (Rh), vanadium (V), zirconium (Zr), other metal, alloys thereof (which may include chlorine (Cl), oxygen (O), nitrogen (N), fluorine (F), other non-metal, or a combination thereof), or a combination thereof. In embodiments where capping layer 116 includes oxygen, an amount of oxygen in capping layer 116 is negligible, such as an atomic ratio of oxygen that is less than about 5 atomic percent (at %). For example, capping layer 116 may have about 0 at % to about 5 at % of oxygen. In some embodiments, capping layer 116 is a ruthenium-comprising layer, such as a ruthenium layer or a ruthenium alloy layer. For example, capping layer 116 may include ruthenium and another metal, and capping layer 116 may be an RuNb layer, an RuZr layer, an RuZrN layer, an RuRh layer, an RuNbN layer, an RuRhN layer, an RuV layer, an RuVN layer, other ruthenium alloy layer, or a combination thereof. In such example, the ruthenium alloy layer may include chlorine, fluorine, negligible amounts of oxygen, or a combination thereof. In another example, capping layer 116 may include ruthenium and oxygen, and capping layer 116 may be an RuO₂ layer, an RuNbO layer, an RiVO layer, an RuON layer, other ruthenium oxide layer, or a combination thereof. In such example, the ruthenium oxide layer may have about 0 at % to about 5 at % of oxygen, and the ruthenium oxide layer may include chlorine, fluorine, or a combination thereof. In some embodiments, capping layer 116 is a silicon-comprising layer, such as a silicon layer. In some embodiments, capping layer 116 has a multilayer structure.

Absorber layer 120′ (also referred to as an absorption layer) is disposed over capping layer 116. Absorber layer 120′ absorbs radiation, such as EUV radiation, directed onto EUV mask 100. In some embodiments, absorber layer 120′ includes tantalum (Ta), boron (B), titanium (Ti), nickel (Ni), chromium (Cr), Ru, platinum (Pt), lanthanum (La), other metal, alloys thereof (which may include O, N, germanium (Ge), other suitable constituent, or a combination thereof), or a combination thereof. In some embodiments, absorber layer 120′ is a tantalum-comprising layer, such as a tantalum layer or a tantalum alloy layer. For example, absorber layer 120′ may include tantalum and nitrogen and/or oxygen, and absorber layer 120′ may be a TaN layer, a TaBO layer, a TaBN layer, a TaBON, other tantalum oxide layer, other tantalum nitride layer, other tantalum oxynitride layer, or a combination thereof. In some embodiments, absorber layer 120′ is a chromium-comprising layer, such as a chromium layer or a chromium alloy layer. For example, absorber layer 120′ may include chromium and nitrogen and/or oxygen, and absorber layer 120′ may be a CrN layer, a CrON layer, a CrCON layer, other chromium nitride layer, other chromium oxynitride layer, or a combination thereof. In some embodiments, absorber layer 120′ has a multilayer structure. For example, absorber layer 120′ may include a first absorber layer (e.g., a metal nitride layer, such as a TaBN layer) over capping layer 116, and a second absorber layer (e.g., a metal oxide layer, such as a TaBO layer) over the first absorber layer. The second absorber layer may function as an antireflective coating (ARC).

In some embodiments, ML structure 110 is disposed over a first side (e.g., a frontside) of substrate 105, and the mask precursor further includes a material layer 122 disposed over a second side (e.g., a backside) of substrate 105 that is opposite the first side of substrate 105. Material layer 122 may also be referred to as a backside coating. In some embodiments, backside coating 122 includes Cr, Ta, other metal, alloys thereof (which may include O, N, other non-metal, or a combination thereof), or a combination thereof. In some embodiments, material layer 122 is a chromium-comprising layer, such as a chromium layer or a chromium alloy layer. For example, material layer 122 may include chromium and nitrogen, and material layer 122 may be a CrN layer, a CrON layer, other chromium nitride layer, or a combination thereof. In some embodiments, material layer 122 is a tantalum-comprising layer, such as a tantalum layer or a tantalum alloy layer. For example, material layer 122 may be a TaBN layer, a TaSi layer, other tantalum alloy layer, or a combination thereof. In some embodiments, material layer 122 is used to secure EUV mask 100 to an electrostatic chuck of an EUV lithography system. In such embodiments, material layer 122 may be referred to as a chucking layer.

Referring to FIG. 1 and FIG. 2A, method 10 at block 20 includes forming a patterned hard mask layer 130 over absorber layer 120′ of the mask precursor. Patterned hard mask layer 130 has one or more openings therein, such as an opening 135, that expose absorber layer 120′. Patterned hard mask layer 130 has a thickness T, and a composition of patterned hard mask layer 130 is different than a composition of absorber layer 120′ and capping layer 116 to enable selective etching. In the depicted embodiment, patterned hard mask layer 130 is a chromium-comprising layer. For example, patterned hard mask layer 130 may be a chromium layer, a chromium oxynitride layer, a chromium nitride layer, other chromium-comprising layer, or a combination thereof. In some embodiments, patterned hard mask layer 130 is a ruthenium-comprising layer. For example, patterned hard mask layer 130 may be a ruthenium layer, a ruthenium boride layer, other ruthenium-comprising layer, or a combination thereof. In some embodiments, patterned hard mask layer 130 is a tantalum-comprising layer. For example, patterned hard mask layer 130 may be a tantalum oxide layer, a tantalum boride layer, a tantalum boron nitride layer, a tantalum boron oxide layer, other tantalum-comprising layer, or a combination thereof. In some embodiments, patterned hard mask layer 130 is a silicon-comprising layer, such as a silicon oxide layer, a silicon nitride layer, a silicon oxynitride layer, a molybdenum silicon layer, other silicon-comprising layer, or a combination thereof.

Forming patterned hard mask layer 130 may include depositing a hard mask layer over absorber layer 120′ and performing a patterning process to remove portions of the hard mask layer. The patterning process may include a lithography process and an etching process. The lithography process may include forming a patterned mask layer (e.g., a patterned resist layer) that covers some portions of the hard mask layer and exposes other portions of the hard mask layer. The etching process may include transferring a pattern in the patterned mask layer to the hard mask layer by removing portions of the hard mask layer that are exposed by the openings in the patterned mask layer. The etching process may selectively remove the hard mask layer with respect to absorber layer 120′ and/or the patterned mask layer. For example, the etching process etches the hard mask layer with no (or negligible) etching of absorber layer 120′ and/or the patterned mask layer. An etchant of the etching process may etch the hard mask layer (e.g., chromium-comprising material) at a higher rate than absorber layer 120′ (e.g., tantalum-comprising material) and/or the patterned mask layer (e.g., resist material). The etching process is a dry etch, a wet etch, other suitable etch, or a combination thereof. In some embodiments, the etching process removes the patterned mask layer, in portion or entirety, from over the hard mask layer. In some embodiments, after the etching process, the patterned mask layer is removed by an etching process and/or a resist stripping process.

Referring to FIG. 1 and FIG. 2B, method 10 at block 25 includes patterning absorber layer 120′ using patterned hard mask layer 130. For example, an etching process transfers a pattern in patterned hard mask layer 130 to absorber layer 120′ by removing portions of absorber layer 120′ that are exposed by openings (e.g., opening 135) in patterned hard mask layer 130. A patterned absorber layer 120 is thus provided, and patterned absorber layer 120 has an opening 138 therein. Opening 138 corresponds with opening 135 in patterned hard mask layer 130 and exposes capping layer 116. The etching process may selectively remove absorber layer 120′ with respect to capping layer 116 and/or patterned hard mask layer 130. For example, the etching process etches absorber layer 120′ with no (or negligible) etching of capping layer 116 and/or patterned hard mask layer 130. An etchant of the etching process may etch absorber layer 120′ (e.g., tantalum-comprising material) at a higher rate than capping layer 116 (e.g., ruthenium-comprising material) and/or patterned hard mask layer 130 (e.g., chromium-comprising material). Capping layer 116 may function as an etch stop layer, and the etching process may stop upon reaching capping layer 116. The etching process is a dry etch, a wet etch, other suitable etch, or a combination thereof.

Absorber layer 120′ may be patterned according to a desired patterning of EUV radiation needed to fabricate a desired feature of a semiconductor device and/or IC. For example, patterned absorber layer 120 may define a layer of a semiconductor device and/or an IC. In some embodiments, patterned absorber layer 120 defines a circuit pattern, and EUV mask 100 may be used to transfer the circuit pattern onto a substrate and/or material layer thereof and/or thereover. In some embodiments, patterned absorber layer 120 defines a routing layer (e.g., a line structure) of a device, such as a via layer or a metallization layer of a multilayer interconnect. In some embodiments, patterned absorber layer 120 defines a contact opening layer (e.g., a hole structure), which may be used to form contact openings that may be subsequently filled with contacts, such as source/drain contacts and/or gate contacts. In some embodiments, patterned absorber layer 120 defines a cavity structure. In some embodiments, patterned absorber layer defines a cut pattern. In some embodiments, EUV mask 100 may be configured as a binary intensity mask (BIM) having absorptive regions (also referred to as opaque regions), which may be regions of EUV mask 100 that include patterned absorber layer 120 (which may absorb EUV light incident thereon), and reflective regions, which may be regions of EUV mask 100 where absorber layer 120′ is removed to expose capping layer 116 and/or ML structure 110 (which may reflect and/or diffract EUV light incident thereon).

Referring to FIG. 1 and FIGS. 2C-2E, method 10 at block 30 includes removing patterned hard mask layer 130. Method 10 implements a two-step etching process for removing patterned hard mask layer 130 that reduces exposure of EUV mask 100 to oxygen. Compared to a single etching process typically used to remove patterned hard mask layer 130, the two-step etching process may reduce oxidation of and/or diffusion of oxygen into capping layer 116, patterned absorber layer 120, ML structure 110, or a combination thereof, thereby improving EUV mask lifetime and/or improving EUV mask repair capability. The two-step etching process includes performing a first etching process 140 to partially remove patterned hard mask layer 130 at block 35 and performing a second etching process 150 to remove a remainder of patterned hard mask layer 130 at block 40. First etching process 140 uses a first etchant, and second etching process 150 uses a second etchant that is different than the first etchant.

Referring to FIG. 2C, first etching process 140 partially removes patterned hard mask layer 130. First etching process 140 may selectively remove patterned hard mask layer 130 with respect to capping layer 116 and/or patterned absorber layer 120. For example, first etching process 140 etches patterned hard mask layer 130 with no (or negligible) etching of capping layer 116 and/or patterned absorber layer 120. The first etchant of first etching process 140 may etch patterned hard mask layer 130 (e.g., chromium-comprising material) at a higher rate than capping layer 116 (e.g., ruthenium-comprising material) and/or patterned absorber layer 120 (e.g., tantalum-comprising material). In the depicted embodiment, the first etchant is a non-oxygen etch gas, which minimizes exposure of EUV mask 100 (e.g., capping layer 116 and/or patterned absorber layer 120 thereof) to oxygen during removal of patterned hard mask layer 130. For example, first etching process 140 is a halogen-based etch that exposes patterned hard mask layer 130 to a halogen-based etchant, such as a halogen etch gas. The halogen etch gas may include chlorine, fluorine, bromine, other halogen constituent, or a combination thereof, and the halogen etch gas may be substantially free of oxygen. In some embodiments, the halogen etch gas is a Cl₂ etch gas and/or other chlorine-containing etch gas. In some embodiments, the halogen-based etch is a plasma etch that exposes patterned hard mask layer 130 to a halogen plasma, such as a Cl₂ plasma etch that exposes patterned hard mask layer 130 to a Cl₂ plasma. In some embodiments, the halogen-based etch is a pure halogen plasma etch.

Referring to FIG. 2D, second etching process 150 removes the remainder of patterned hard mask layer 130. Second etching process 150 may selectively remove patterned hard mask layer 130 with respect to capping layer 116 and/or patterned absorber layer 120. For example, second etching process 150 etches patterned hard mask layer 130 with no (or negligible) etching of capping layer 116 and/or patterned absorber layer 120. The second etchant of second etching process 150 may etch patterned hard mask layer 130 (e.g., chromium-comprising material) at a higher rate than capping layer 116 (e.g., ruthenium-comprising material) and/or patterned absorber layer 120 (e.g., tantalum-comprising material). The second etchant may also etch patterned mask layer 130 at a higher rate than the first etchant (i.e., etch speed/rate of first etching process 140 is less than etch speed/rate of second etching process 150). In the depicted embodiment, the second etchant is an oxygen etch gas. For example, second etching process 150 is a halogen-and-oxygen based etch that exposes patterned hard mask layer 130 to a halogen-and-oxygen based etchant, such as a halogen-and-oxygen etch gas. The halogen-and-oxygen etch gas includes a halogen constituent (e.g., chlorine, fluorine, bromine, other halogen constituent, or a combination thereof) and oxygen. In some embodiments, the halogen-and-oxygen etch gas includes an O₂ etch gas and a Cl₂ etch gas. In some embodiments, the halogen-and-oxygen based etch is a plasma etch that exposes patterned hard mask layer 130 to a halogen-and-oxygen plasma, such as an O₂+Cl₂ plasma etch that exposes patterned hard mask layer 130 to an O₂+Cl₂ plasma. In some embodiments, the halogen-and-oxygen based etch and the halogen-based etch use the same halogen constituent(s). In some embodiments, the halogen-and-oxygen based etch and the halogen-based etch use different halogen constituents.

During second etching process 150, an oxide layer 160 may form over patterned absorber layer 120. Oxide layer 160 includes oxygen and may further include chlorine, metal (e.g., metal(s) of patterned absorber layer 120, such as tantalum and/or chromium), or a combination thereof. In some embodiments, oxide layer 160 is a metal oxide layer, such as a tantalum oxide layer or a chromium oxide layer. In some embodiments, oxide layer 160 is a metal oxychloride layer, such as a tantalum oxychloride layer or a chromium oxychloride layer. In some embodiments, during second etching process 150, a chloride layer may form over patterned absorber layer 120, and 160 in FIG. 2D may be a chloride layer, instead of an oxide layer. In such embodiments, the chloride layer may include chlorine and may further include oxygen, metal (e.g., metal(s) of patterned absorber layer 120), or a combination thereof.

Further, during second etching process 150, oxygen may diffuse into exposed portions of capping layer 116. For example, oxygen diffuses into a portion of capping layer 116 exposed by opening 138 in patterned absorber layer 120, thereby forming an oxygen diffusion region 116o in capping layer 116. Because second etching process 150 removes thickness t1, instead of thickness T, of patterned hard mask layer 130 (i.e., a remainder thereof), EUV mask 100 is exposed to second etching process 150 for a shorter duration/time. EUV mask 100 is thus exposed to an oxygen etch gas for a shorter duration/time, which reduces an amount of oxygen diffusion into capping layer 116. Though some oxygen may diffuse into capping layer 116, the two-step etching process limits an amount of oxygen diffusing into capping layer 116 to acceptable levels, such as an atomic ratio of oxygen in capping layer 116 that may be tolerated to enable quick removal of patterned hard mask layer 130 (as provided by second etching process 150) but that may hinder and/or prevent oxidation of capping layer 116 and/or ML structure 110 (and thus improve a lifetime of EUV mask 100). For example, an atomic ratio of oxygen in the exposed portion of capping layer 116 and/or oxygen diffusion region 116o therein is less than about 10%. Since patterned absorber layer 120 may block oxygen from diffusing into capping layer 116, oxygen may diffuse into exposed portion of capping layer 116 but not covered portions of capping layer 116 (e.g., those portions covered by patterned absorber layer 120), which may result in exposed portion of capping layer 116 and covered portions of capping layer 116 having different oxygen amounts. In some embodiments, an atomic ratio of oxygen in exposed portion of capping layer 116 is greater than an atomic ratio of oxygen in covered portions of capping layer 116, and both the exposed portion of capping layer 116 and the covered portions of capping layer 116 have an atomic ratio of oxygen that is less than about 10%. For example, the covered portions of capping layer 116 may have an atomic ratio of oxygen that is less than about 5%, while the exposed portion of capping layer 116 may have an atomic ratio of oxygen that is about 5% to about 10%, which may be a result of oxygen diffusion that may occur during second etching process 150. Atomic ratios of oxygen greater than 10% may enable undesired oxidation of capping layer 116 and/or ML structure 110 that may degrade performance of EUV mask 100 (e.g., by decreasing its reflectivity) and/or decrease its lifetime.

In some embodiment, since oxygen may diffuse into some regions (e.g., a top region at top surface of capping layer 116) of the exposed portion of capping layer 116 but not other regions (e.g., a bottom region at a bottom surface of capping layer 116 that interfaces with ML structure 110) of the exposed portion of capping layer 116, the exposed portion of capping layer 116 may have different oxygen amounts. For example, an atomic ratio of oxygen diffusion region 116o of the exposed portion of capping layer 116 is greater than an atomic ratio of oxygen of a region of the exposed portion of capping layer 116 that is outside oxygen diffusion region 116o (e.g., a region of the exposed portion of capping layer 116 that is between a bottom of oxygen diffusion region 116o and ML structure 110). For example, oxygen diffusion region 116o may have an atomic ratio of oxygen that is about 5% to about 10%, and the region of the exposed portion of capping layer 116 that is outside oxygen diffusion region 116o may have an atomic ratio of oxygen that is less than about 5%. In some embodiments, oxygen diffusion region 116o may be wrapped by a region of the exposed portion of capping layer 116 that is outside oxygen diffusion region 116o (i.e., a region where oxygen may not have diffused during second etching process 150). The present disclosure contemplates various profiles of oxygen in the exposed portion of capping layer 116, such that the exposed portion of capping layer 116 may have various configurations of oxygen diffusion region 116o therein. In some embodiments, the exposed portion of capping layer 116o may have multiple oxygen diffusion regions 116o, which may have the same or different amounts of oxygen.

Because first etching process 140 (e.g., a halogen-based etch) implements a non-oxygen etch gas, an oxide layer will not form over patterned absorber layer 120 and oxygen will not diffuse into capping layer 116 (and thus undesirably increase an oxygen content in capping layer 116) during first etching process 140, which reduces oxygen exposure of EUV mask 100 during removal of patterned hard mask layer 130. However, because first etching process 140 is milder, patterned hard mask layer 130 is removed slowly by first etching process 140, and patterned absorber layer 120 may be damaged (e.g., halogenated, such as chlorinated) if first etching process 140 lasts too long. In contrast, because second etching process 150 (e.g., a halogen-and-oxygen based etch) implements an oxygen etch gas, second etching process 150 may remove patterned hard mask layer 130 faster than first etching process 140, which may improve throughput. However, because second etching process 150 implements the oxygen etch gas, oxygen diffuses into capping layer 116, patterned absorber layer 120, ML structure 110, or a combination thereof, and oxide layer 160 forms over patterned absorber layer 120. Accordingly, parameters of first etching process 140 and second etching process 150 are tuned to minimize a time needed to remove patterned hard mask layer 130, minimize damage to EUV mask 100 (e.g., to patterned absorber layer 120 by first etching process 140), and minimize exposure of EUV mask 100 to oxygen (e.g., thereby reducing oxygen in capping layer 116 and thus detrimental oxidation of EUV mask 100), thereby optimizing throughput, a lifetime of EUV mask 100, durability of EUV mask 100 during mask repair, or a combination thereof.

Parameters of first etching process 140 and second etching process 150 that may be tuned include etch gas composition, etch gas flow rate, time/duration, pressure, temperature, bias power, source power (e.g., radio frequency (RF) power), other etch parameter(s), or a combination thereof. In some embodiments, durations/times of first etching process 140 and second etching process 150 are configured based on a thickness of patterned hard mask layer 130. For example, first etching process 140 may reduce a thickness of patterned hard mask layer 130 from thickness T to a thickness t1 by removing a thickness t2 of patterned hard mask layer 130 (FIG. 2C) and second etching process 150 may remove thickness t1 of patterned hard mask layer 130 (FIG. 2D). Thickness t2 may be greater than or equal to thickness t1 (e.g., t2≥t1). In some embodiments, the two-step etching process switches from first etching process 140 to second etching process 150 when a thickness of patterned hard mask layer 130 is reduced by first etching process 140 to a predetermined percentage of its original thickness (i.e., t1=x % of T). For example, the two-step etching process may switch from first etching process 140 to second etching process 150 when thickness t1 is about 30% to about 50% of thickness T (e.g., 0.3T≤t1≤0.5T). In such example, thickness t2 may be about 50% to about 70% of thickness T (e.g., 0.5T≤t2≤0.7T). If an insufficient amount of patterned hard mask layer 130 is removed by first etching process 140 (e.g., t1<0.3T), a duration of second etching process 150 may need to be longer to ensure removal of a thicker remainder of patterned hard mask layer 130, which may result in EUV mask 100 being exposed to oxygen etch gas for too long, such as a time that enables too much oxygen diffusion into EUV mask 100 and/or oxidation of EUV mask 100. If an excess amount of patterned hard mask layer 130 is removed by first etching process 140 (e.g., t1>0.5T), a duration of first etching process 140 may be too long, which may result in first etching process 140 damaging EUV mask (e.g., by halogenating patterned absorber layer 120). In some embodiments, thickness t1 is a predetermined thickness (or percentage of original thickness T) that minimizes exposure of EUV mask to oxygen while minimizing a time needed to remove patterned hard mask layer 130. In some embodiments, thickness t2 is less than thickness t1. In some embodiments, first etching process 140 and second etching process 150 are performed in the same process chamber. In some embodiments, first etching process 140 and second etching process 150 are performed in different process chambers.

In some embodiments, second etching process 150 implements an amount of halogen etch gas that is greater than an amount of oxygen etch gas. For example, a flow rate (e.g., in standard cubic centimeters per minute (sccm)) of halogen etch gas may be greater than a flow rate of oxygen etch gas. In some embodiments, the second etching process 150 implements a ratio of a flow rate of halogen etch gas (e.g., Cl₂ gas) to a flow rate of oxygen etch gas (e.g., O₂ gas) that is about 3:1 to about 10:1 (i.e., the flow rate of halogen etch gas is about three to ten times greater than the flow rate of oxygen etch gas). In some embodiments, second etching process 150 implements a pressure of about 1 millitorr (mTorr) to about 6 mTorr. In some embodiments, second etching process 150 implements a source power of about 100 Watts (W) to about 500 W. In some embodiments, second etching process 150 implements a bias power of about 15 W to about 100 W. In some embodiments, first etching process 140 implements a pressure of about 0.5 mTorr to about 2.5 mTorr. In some embodiments, first etching process 140 implements a source power of about 100 W to about 400 W. In some embodiments, first etching process 140 implements a bias power of about 20 W to about 50 W.

Referring to FIG. 2E, oxide layer 160 covers a top of patterned absorber layer 120, wraps top corners 120t of patterned absorber layer 120, and partially covers sidewalls of patterned absorber layer 120. For example, a distance d is between oxide layer 160 and a top of capping layer 116 (and/or bottom corners 120b of patterned absorber layer 120), such that oxide layer 160 does not directly, physically contact capping layer 116, in the depicted embodiment. In some embodiments, such as depicted in FIG. 3, oxide layer 160 covers sidewalls of patterned absorber layer 120 and extends to bottom corners 120b of patterned absorber layer 120. In such embodiments, a tip of oxide layer 160 may directly, physically contact bottom corners 120b of patterned absorber layer 120 and capping layer 116. In some embodiments, such as depicted in FIG. 4, oxide layer 160 covers sidewalls of patterned absorber layer 120 and extends to capping layer 116. In such embodiments, oxide layer 160 may directly, physically contact bottom corners 120b of patterned absorber layer 120 and capping layer 116. Parameters of first etching process 140 and second etching process 150 may be tuned to hinder and/or prevent formation of oxide layer 160 on capping layer 116, such that a top of the exposed portion of capping layer 116 is substantially free of oxide layer 160, such as depicted in FIG. 2E, FIG. 3, and FIG. 4. Further, parameters of first etching process 140 and second etching process 150 may be tuned to minimize formation of oxide layer 160 proximate capping layer 116.

Oxide layer 160 has a thickness t3 over a top of patterned absorber layer 120 and a thickness t4 over sidewalls of patterned absorber layer 120. Thickness t3 and thickness t4 vary over top and sidewalls, respectively, of patterned absorber layer 120. In other words, oxide layer 160 has a non-uniform thickness. Thickness t3 may be about equal to, greater than, or less than thickness t4. In some embodiments, such as depicted in FIG. 2E and FIG. 3, oxide layer 160 has a tip region 160t proximate to bottom corners 120b of patterned absorber layer 120 and/or capping layer 116. Tip region 160t has a thickness that decreases from about thickness t4 to a minimum thickness tₘᵢₙ at the tip of oxide layer 160. In some embodiments, minimum thickness tₘᵢₙ is less than about 5% of thickness t3 (i.e., tₘᵢₙ≤0.05*t3). In some embodiments, such as depicted in FIG. 4, a thickness of a bottom region 160b of oxide layer 160 that directly, physically contacts capping layer 116 is less than about 5% of thickness t3 (i.e., t4 at bottom region 120b≤0.05*t3). In some embodiments, a thickness of oxide layer 160 wrapping top corners 120b of patterned absorber layer 120 is less than thickness t3 and/or thickness t4. In some embodiments, a minimum thickness of oxide layer 160 is adjacent to and may contact bottom corners 120b of patterned absorber layer 120 and/or capping layer 116. Parameters of first etching process 140 and second etching process 150 may be tuned to limit a thickness of oxide layer 160 proximate to capping layer 116 and/or bottom corners 120b of patterned absorber layer 120, thickness t3, thickness t4, or a combination thereof.

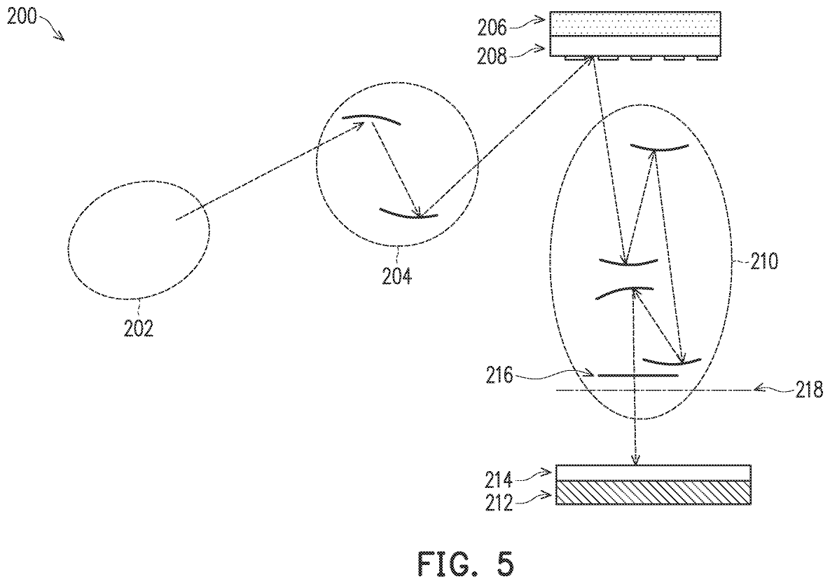

FIG. 5 is a schematic view of a lithography system 200, in portion or entirety, that may implement the EUV masks described herein, such as EUV mask 100, according to various aspects of the present disclosure. Lithography system 200 may generically be referred to as a scanner that is operable to perform lithographic processes including exposure with a respective radiation source and in a particular exposure mode. In some embodiments, lithography system 200 is an EUV lithography system designed to expose a resist layer by EUV light. In such embodiments, the resist layer includes a material that is sensitive to the EUV light (e.g., an EUV resist). Lithography system 200 may include a plurality of subsystems, such as a radiation source 202, an illuminator 204, a mask stage 206 configured to receive a mask 208, projection optics 210, and a substrate stage 212 configured to receive a substrate 214. Generally, lithography system 200 may operate as follows: EUV light from radiation source 202 is directed toward illuminator 204 (which may include a set of reflective mirrors) and projected onto mask 208 (e.g., a reflective mask, such as EUV mask 100), and a reflected mask image is directed toward projection optics 210, which focuses the EUV light and projects the EUV light onto substrate 214 to expose an EUV resist layer deposited thereon. In some embodiments, each subsystem may be housed in, and thus operate within, a high-vacuum environment, for example, to reduce atmospheric absorption of EUV light. FIG. 5 has been simplified for the sake of clarity to better understand the inventive concepts of the present disclosure. Additional features can be added in lithography system 200, and some of the features described below can be replaced or eliminated for additional embodiments of lithography system 200.

Radiation source 102 may generate the EUV light. In some embodiments, radiation source 102 includes a plasma source, such as a discharge produced plasma (DPP) or a laser produced plasma (LPP). In some embodiments, the EUV light may include light having a wavelength ranging from about 1 nm to about 100 nm. In some embodiments, radiation source 102 generates EUV light with a wavelength centered at about 13.5 nm. In some embodiments, radiation source 202 includes a collector, which may collect EUV light generated from a plasma source and direct the EUV light toward imaging optics, such as illuminator 204.

As described above, light from radiation source 202 is directed toward illuminator 204. In some embodiments, illuminator 204 includes reflective optics, such as a single mirror or a mirror system having multiple mirrors, in order to direct light from radiation source 202 onto mask stage 206, and particularly onto mask 208 secured on mask stage 206. In some embodiments, illuminator 204 may include a zone plate, for example, to improve focus of the EUV light. In some embodiments, illuminator 204 may be configured to shape the EUV light passing therethrough in accordance with a particular pupil shape, and the EUV light may have a dipole shape, a quadrupole shape, an annular shape, a single beam shape, a multiple beam shape, or a combination thereof. In some embodiments, illuminator 204 is operable to configure the mirrors (i.e., of illuminator 204) to provide a desired illumination to mask 208. For example, the mirrors of illuminator 204 are configurable to reflect EUV light to different illumination positions. In some embodiments, a stage before illuminator 204 may additionally include other configurable mirrors that may be used to direct the EUV light to different illumination positions within the mirrors of illuminator 204. In some embodiments, illuminator 204 is configured to provide an on-axis illumination (ONI) to mask 208. In some embodiments, illuminator 204 is configured to provide an off-axis illumination (OAI) to mask 208. It should be noted that the optics employed in lithography system 200, and in particular, optics used for illuminator 204 and projection optics 210, may include mirrors having multilayer thin-film coatings known as Bragg reflectors. By way of example, such a multilayer thin-film coating may include alternating layers of Mo and Si, which provides for high reflectivity at EUV wavelengths.

As discussed above, lithography system 200 also includes mask stage 206 configured to secure mask 208. Since lithography system 200 may be housed in, and thus operate within, a high-vacuum environment, mask stage 206 may include an electrostatic chuck (e-chuck) to secure mask 208. As with the optics of lithography system 200, mask 208 is also reflective. Mask 208 may be fabricated according to method 100 of FIG. 1, and mask 208 may be EUV mask 100 of FIG. 2E, FIG. 3, or FIG. 4. As illustrated in the example of FIG. 5, the EUV light is reflected from mask 208 and directed towards projection optics 210, which collects the EUV light reflected from mask 208. By way of example, the EUV light collected by projection optics 210 (reflected from mask 208) carries an image of a pattern defined by mask 208. In some embodiments, projection optics 210 provides for imaging the pattern of mask 208 onto substrate 214 secured on substrate stage 212. For example, projection optics 210 may focus the collected EUV light and project the EUV light onto substrate 214 to expose an EUV resist layer deposited on substrate 214. As described above, projection optics 210 may include reflective optics, as used in EUV lithography systems. In some embodiments, illuminator 204 and projection optics 210 are collectively referred to as an optical module of lithography system 200.

In some embodiments, lithography system 200 also includes a pupil phase modulator 216 to modulate an optical phase of the EUV light directed from mask 208, such that the light has a phase distribution along a projection pupil plane 218. In some embodiments, pupil phase modulator 216 includes a mechanism to tune the reflective mirrors of projection optics 210 for phase modulation. For example, in some embodiments, the mirrors of projection optics 210 are configurable to reflect the EUV light through pupil phase modulator 216, thereby modulating the phase of the light through projection optics 210. In some embodiments, pupil phase modulator 216 utilizes a pupil filter placed on projection pupil plane 218. For example, the pupil filter may be employed to filter out specific spatial frequency components of the EUV light reflected from mask 208. In some embodiments, the pupil filter may serve as a phase pupil filter that modulates the phase distribution of the light directed through projection optics 210.

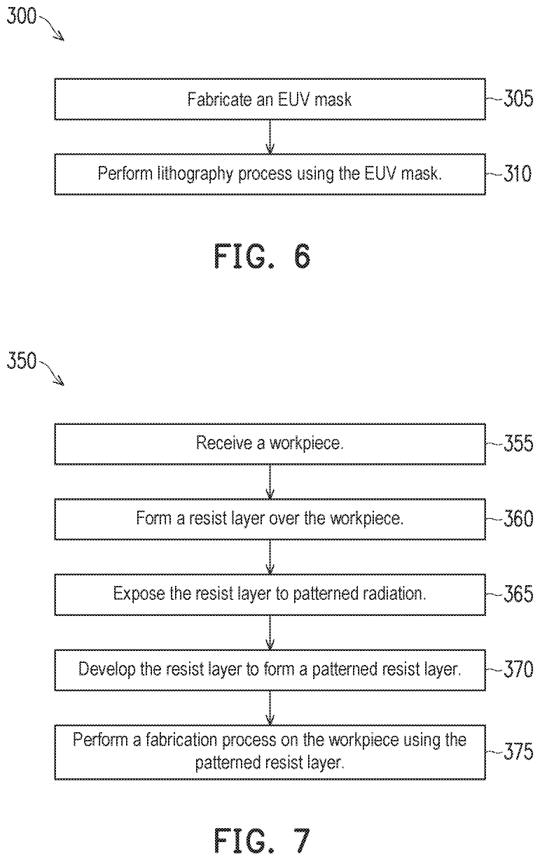

FIG. 6 is a flow chart of a method 300, in portion or entirety, for fabricating and using an EUV mask, such as EUV mask 100, according to various aspects of the present disclosure. Method 300 at block 305 includes fabricating an EUV mask, such as EUV mask 100 of FIG. 2E, FIG. 3, or FIG. 4. An EUV mask fabrication process may include two process stages: a mask blank fabrication process and a mask patterning process. In some embodiments, a mask blank fabrication process includes depositing suitable layers (e.g., a multilayer structure) on a substrate, such as ML structure 110 over substrate 105. The mask blank fabrication process may further include forming a capping layer, such as capping layer 116, over the multilayer structure, and forming an absorber layer, such as absorber layer 120, over the capping layer. In some embodiments, a mask patterning process includes patterning a mask blank to form a desired pattern on the EUV mask. For example, the mask patterning process includes forming a patterned hard mask, such as patterned hard mask layer 130, over the absorber layer and patterning the absorber layer, such as described above with reference to FIGS. 2A-2E. In some embodiments, a pattern formed in the absorber layer defines features of a semiconductor device and/or an IC, or a layer of a semiconductor device and/or an IC. In some embodiments, an ARC layer may be deposited over the absorber layer before patterning the mask blank.

Method 300 at block 310 includes performing a lithography process using the EUV mask, such as EUV mask 100. For example, the EUV mask may be used to transfer a circuit pattern and/or a device pattern onto a workpiece using an EUV lithography system (e.g., lithography system 200). In some embodiments, the EUV mask is loaded/secured onto a mask stage of the EUV lithography system, and the workpiece is loaded/secured onto a substrate stage of the EUV lithography system. In operation, EUV light from a radiation source of the EUV lithography system may be directed toward an illuminator of the EUV lithography system and projected onto the EUV mask. A reflected mask image may then be directed toward projection optics of the EUV lithography system, which focuses the EUV light and projects the EUV light onto the workpiece to expose an EUV resist layer deposited thereupon, thereby transferring a pattern from the EUV mask to the workpiece. In some embodiments, the pattern defined by the EUV mask may be transferred over and over onto multiple workpieces through various lithography processes. Fabricating the EUV mask as described herein may extend a lifetime of the EUV mask for use in the various lithography processes, which improves IC fabrication. In addition, a set of EUV masks, each of which may be fabricated as described herein, may be used to construct a complete semiconductor device and/or IC. FIG. 6 has been simplified for the sake of clarity to better understand the inventive concepts of the present disclosure. Additional steps may be provided before, during, and after method 300, and some of the steps described may be moved, replaced, or eliminated for additional embodiments of method 300.

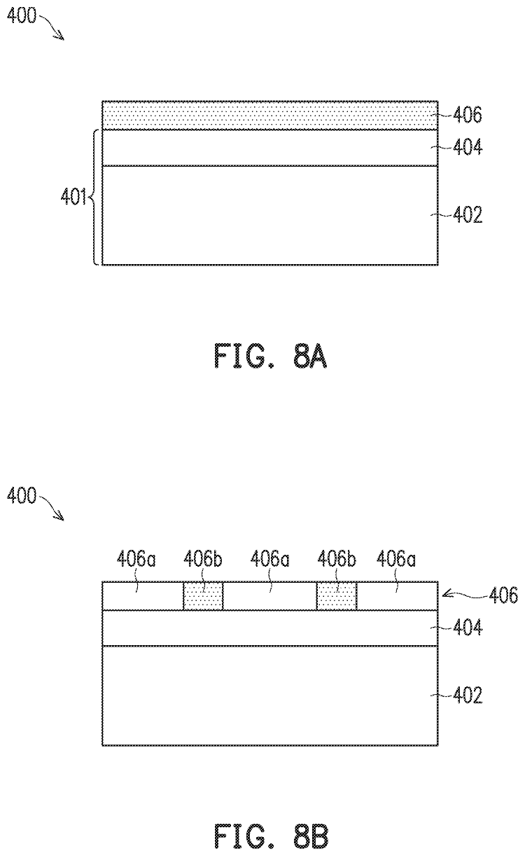

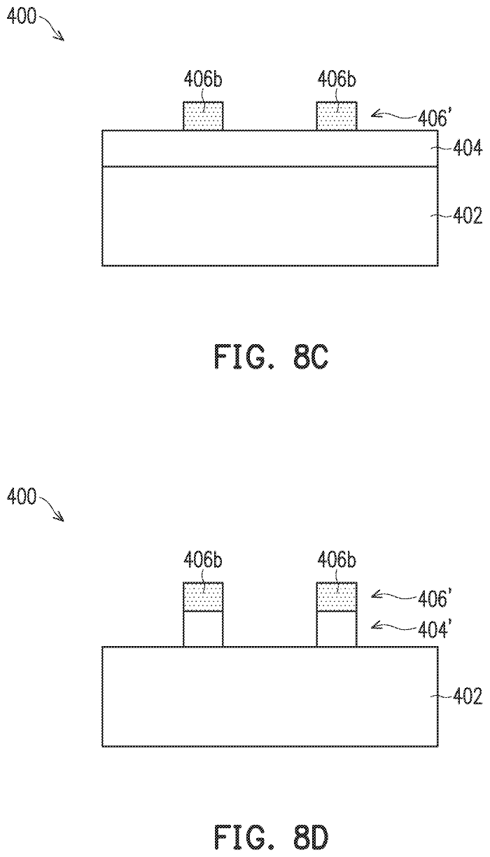

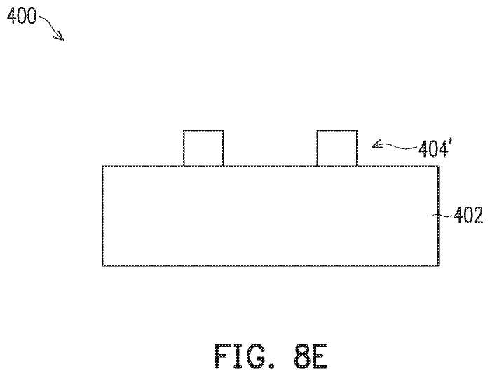

FIG. 7 is a flow chart of a method 350, in portion or entirety, for fabricating a semiconductor device and/or an IC using an EUV mask, such as EUV mask 100, according to various aspects of the present disclosure. Method 350 may be implemented, in whole or in part, by a lithography system, such as EUV system 200. However, in some embodiments, portions of method 350 may be implemented by another type of lithography system, such as a DUV lithography system, an electron beam lithography system, an X-ray lithography system, other lithography system, or a combination thereof. FIGS. 8A-8E are cross-sectional views of a semiconductor device 400, in portion or entirety, at various fabrication stages associated with method 350 of FIG. 7, according to various aspects of the present disclosure. FIG. 7 and FIGS. 8A-8E are discussed concurrently herein for ease of description and understanding. FIG. 7 and FIGS. 8A-8E have been simplified for the sake of clarity to better understand the inventive concepts of the present disclosure. Additional steps may be provided before, during, and after method 350 of FIG. 7, and some of the steps described may be moved, replaced, or eliminated for additional embodiments of method 350 of FIG. 7. Additional features may be added in semiconductor device 400, and some of the features described below may be replaced, modified, or eliminated in other embodiments of semiconductor device 400.

Referring to FIG. 7 and FIG. 8A, method 350 at block 355 includes receiving a workpiece 401, which may include a device substrate 402. Device substrate 402 may include a substrate, such as a semiconductor substrate on which processing may be conducted to provide patterned layers of material to form various features and/or components of a semiconductor device and/or an IC. Depending on fabrication stage, device substrate 402 may include various material layers (e.g., dielectric layers, semiconductor layers, metal layers, or a combination thereof) configured to form device features and/or components, such as doped regions (e.g., n-type regions and/or p-type regions), isolation features (e.g., shallow trench isolation (STI) structures and/or other suitable isolation structures), metal gates (e.g., a metal gate having a gate electrode over a gate dielectric), gate spacers along sidewalls of the metal gates, source/drain features (e.g., epitaxial source/drains), dummy gates, source/drain contacts, gate contacts, vias, metal lines, other device features and/or components, or a combination thereof.

Workpiece 401 may further include a material layer 404 to be processed (e.g., to be patterned by etching and/or implantation) disposed over substrate 402. In some embodiments, material layer 404 (also referred to as an underlayer) includes a hard mask layer to be patterned for use in subsequent processing of substrate 402. For example, the patterned hard mask layer (i.e., patterned material layer 404) may be used to etch or implant substrate 402 or a material layer thereof. The hard mask layer may include silicon oxide, silicon nitride, silicon oxynitride, titanium nitride, other suitable material and/or composition, or a combination thereof. In some embodiments, material layer 404 may include an anti-reflection coating (ARC) layer, such as a nitrogen-free anti-reflection coating (NFARC) layer. In some embodiments, material layer 404 includes a semiconductor layer including silicon, germanium, other suitable semiconductor constituent, or a combination thereof. In some embodiments, material layer 404 includes a metal layer including titanium, aluminum, tungsten, tantalum, copper, cobalt, ruthenium, alloys thereof, other suitable metal constituent and/or alloys thereof, or a combination thereof. In some embodiments, material layer 404 includes a dielectric layer including silicon and oxygen, nitrogen, carbon, other suitable dielectric constituent, or a combination thereof. In some embodiments, material layer 404, once patterned, may be used to form a gate feature, such as a gate dielectric and/or a gate electrode, a source/drain, such as an epitaxial source/drain, or an interconnect feature, such as a conductive structure or a dielectric layer of a multilayer interconnect of semiconductor device 400. The present disclosure contemplates embodiments where material layer 404 is omitted from workpiece 401 and substrate 402 is directly processed and embodiments where material layer 404 includes more than one material layer.

Referring to FIG. 7 and FIG. 8A, method 350 at block 360 includes forming a resist layer 406 over workpiece 401 (e.g., over substrate 402 and/or material layer 404) by a suitable process. Resist layer 406 may be referred to as a photoresist layer, a photosensitive layer, an imaging layer, a patterning layer, a radiation sensitive layer, or a combination thereof. Resist layer 406 is sensitive to radiation used during a lithography exposure process, and resist layer 406 has a resistance to a process to be performed on workpiece 401, such as resistance to an etching process and/or an implantation process. In the depicted embodiment, resist layer 406 is sensitive to EUV radiation (e.g., 13.5 nm radiation) and may be referred to as an EUV resist, and resist layer 406 has a resistance to an etching process to be performed on material layer 404. In some embodiments, resist layer 406 is sensitive to DUV radiation (e.g., 248 nm radiation, such as from a KrF laser, and/or 193 nm radiation, such as from an ArF laser), EUV radiation (e.g., 13.5 nm radiation), an electron beam (e-beam), an ion beam, other radiation, or a combination thereof. In some embodiments, resist layer 406 is formed by a spin-coating process. In some embodiments, after forming resist layer 406 and before performing an exposure process, a pre-bake process may be performed, for example, to evaporate solvent and/or to densify resist layer 406. In some embodiments, before forming resist layer 406, an antireflective (ARC) layer and/or an adhesion layer is formed over material layer 404. In some embodiments, resist layer 406 is soluble in a positive tone developer or a negative tone developer after exposure.

Referring to FIG. 7 and FIG. 8B, method 350 at block 365 includes exposing resist layer 406 to patterned radiation (i.e., an exposure process is performed on resist layer 406). In FIG. 8B, resist layer 406 has been exposed (e.g., by a lithography system) through an intervening mask, and resist layer 406 has been illuminated with patterned radiation. For example, resist layer 406 has been exposed by EUV radiation (e.g., 13.5 nm) through an EUV mask (e.g., EUV mask 100) using an EUV system (e.g., lithography system 200). Alternatively, resist layer 406 may be exposed by DUV radiation (e.g., from a 248 nm KrF excimer laser or a 193 nm ArF excimer laser), x-ray radiation, an e-beam, an ion beam, other radiation source, or a combination thereof. In some embodiments, a baking process is performed after the exposure process. For example, after exposure of resist layer 406 and before development, a post-bake process may be performed to stabilize and harden the exposed resist layer. In some embodiments, and as a result of the exposure process, a latent pattern is formed in resist layer 406. By way of example, the latent pattern refers to the exposed pattern on resist layer 406, which will subsequently become a physical resist pattern, after a development process. In some embodiments, the latent pattern of resist layer 406 may include unexposed portions 406a and exposed portions 406b. Exposed portions 406b of resist layer 406 may be physically or chemically changed as a result of the exposure process. In some embodiments, if resist layer 406 is a positive-tone resist, exposed portions 406b will dissolve during a subsequent development process. In some embodiments, if resist layer 406 is a negative-tone resist, exposed portions 406b will become insoluble and a subsequent development process may instead dissolve unexposed portions 406a.

Referring to FIG. 7 and FIG. 8C, method 350 at block 370 includes developing resist layer 406 to form a patterned resist layer 406′ (i.e., a resist development process is performed on exposed resist layer 406). For example, after formation of the latent image in resist layer 406 (e.g., provide by exposed portions 406b and unexposed portions 406a), a developer is applied to resist layer 406 that removes/dissolves unexposed portions 406a thereof, and exposed portions 406b remain over material layer 404 and provide patterned resist layer 406′. In the depicted embodiment, use of a negative-tone resist is illustrated, where portions of resist layer 406 exposed to radiation (i.e., exposed portions 406b) become insoluble and remain after the development process. In some embodiments, a developer is applied to resist layer 406 that removes/dissolves exposed portions 406b thereof, and unexposed portions 406a remain over material layer 404 and provide patterned resist layer 406′. In some embodiments, a development process includes a wet chemical development process. In some embodiments, a rinsing process is performed after the development process, for example, to remove any residue and/or particles from workpiece 401. In some embodiments, a post-development baking (PDB) process is performed, for example, to ensure structural stability of patterned resist layer 406′.

Referring to FIG. 7 and FIG. 8D, method 350 at block 375 includes performing a fabrication process on workpiece 400, such as material layer 404 and/or substrate 402 thereof, using patterned resist layer 406′. For example, a fabrication process may be performed on workpiece 400 using patterned resist layer 406′ as a mask, and the fabrication process may be applied to portions of workpiece 400 within openings of patterned resist layer 406′ (e.g., exposed regions of material layer 404), while other portions of workpiece 400 are covered by patterned resist layer 406′ and protected from the fabrication process. In the depicted embodiment, the fabrication process includes performing an etching process on material layer 404 using patterned resist layer 406′ as an etch mask, thereby transferring a pattern from patterned resist layer 406′ to material layer 404. For example, the etching process removes exposed portions of material layer 404, and unexposed portions of material layer 404 remain and provide a patterned material layer 404′ over substrate 402. The etching process may be a dry etch, a wet etch, other suitable etch, or a combination thereof. In embodiments where material layer 204 is a hard mask layer (or other type of patterning layer), the pattern is first transferred from patterned resist layer 406′ to material layer 404, and then the pattern is transferred from patterned material layer 404′ to substrate 402 or a material layer thereof, for example, by etching or implantation. In such embodiments, patterned resist layer 406′ may be removed before or after transferring the pattern to substrate 402. Alternatively, in some embodiments, the fabrication process includes performing an implantation process on material layer 404 using patterned resist layer 406′ as an implant mask, thereby forming various doped features (regions) in material layer 404.

Referring to FIG. 8E, patterned resist layer 406′ is removed by a suitable process, such as a resist stripping process, thereby leaving patterned material layer 404′ over substrate 402. In some embodiments, patterned resist layer 406′ may be partially or completely consumed during etching of material layer 404 and formation of patterned material layer 404′. In some embodiments, any portion of patterned resist layer 406′ remaining after the etching process may be removed by a stripping process. It is noted that the present disclosure also contemplates embodiments where, instead of patterning material layer 404 with patterned resist layer 406′, the fabrication process includes depositing a material over patterned resist layer 406′ that fills opening(s) therein and removing patterned resist layer 406′ after the depositing, thereby forming patterned material features over material layer 404 (e.g., conductive lines).

Semiconductor device 400 may be an intermediate device fabricated during processing of an IC, or a portion thereof, that may include logic circuits, memory structures, passive components (such as resistors, capacitors, and inductors), and active components, such as diodes, field-effect transistors (FETs), metal-oxide semiconductor field effect transistors (MOSFET), complementary metal-oxide semiconductor (CMOS) transistors, bipolar transistors, high voltage transistors, high frequency transistors, fin-like FETs (FinFETs), other three-dimensional (3D) FETs, metal-oxide semiconductor field effect transistors (MOSFET), complementary metal-oxide semiconductor (CMOS) transistors, bipolar transistors, high voltage transistors, high frequency transistors, other memory cells, or a combination thereof.

The present disclosure provides for many different embodiments. EUV mask and methods of fabrication therein are described herein and provide numerous advantages. An exemplary method includes receiving an EUV mask having a multilayer structure, a capping layer disposed over the multilayer structure, a patterned absorber layer disposed over the capping layer, and a patterned hard mask disposed over the patterned absorber layer. The method further includes removing the patterned hard mask by performing a first etching process to partially remove the patterned hard mask and performing a second etching process to remove a remainder of the patterned hard mask. The first etching process uses a first etchant, and the second etching process uses a second etchant. The second etchant is different than the first etchant.

In some embodiments, the first etchant is a halogen-based plasma, and the second etchant is a halogen-and-oxygen-based plasma. In some embodiments, the halogen-based plasma is a Cl₂ plasma, and the halogen-and-oxygen-based plasma is a Cl₂+O₂ plasma. In some embodiments, the method further includes performing the second etching process after the first etching process has reduced the patterned hard mask from a first thickness to a second thickness. The second thickness may be about 30% to about 50% of the first thickness.

In some embodiments, the first etching process removes the patterned hard mask at a first etch rate, the second etching process removes the patterned hard mask at a second etch rate, and the second etch rate is greater than the first etch rate. In some embodiments, the patterned absorber layer exposes a portion of the capping layer, and the method further includes tuning parameters of the first etching process and the second etching process to control oxygen diffusion into the exposed portion of the capping layer, wherein an atomic ratio of oxygen in the exposed portion of the capping layer is limited to less than about 10%.

In some embodiments, the method further includes forming an oxide layer on the patterned absorber layer when removing the patterned hard mask. In some embodiments, the patterned absorber layer exposes a top of a portion of the capping layer, and the method further includes tuning parameters of the first etching process and the second etching process to prevent the oxide layer from forming on the top of the portion of the capping layer.

In some embodiments, the oxide layer has a first portion disposed on a top of the patterned absorber layer and a second portion disposed on sidewalls of the patterned absorber layer. The first portion of the oxide layer may have a first thickness, the second portion of the oxide layer may have a second thickness, and the second portion of the oxide layer may have a tip having a third thickness that is less than the second thickness. In some embodiments, the method further includes tuning parameters of the first etching process and the second etching process to limit the third thickness of the tip to less than 5% of the first thickness. In some embodiments, the tip physically contacts a bottom corner of the patterned absorber layer. In some embodiments, the third thickness is a minimum thickness of the oxide layer.

A method for fabricating an extreme ultraviolet (EUV) mask includes forming a capping layer over a multilayer structure, forming an absorber layer over the capping layer, forming a patterning layer over the absorber layer, and selectively etching the absorber layer with respect to the capping layer using the patterning layer as an etch mask. The method further includes selectively etching the patterning layer with respect to the capping layer and the absorber layer. The selectively etching of the patterning layer includes a first etch step that uses a non-oxygen etchant to partially remove the patterning layer and a second etch step that uses an oxygen etchant to remove a remainder of the patterning layer. In some embodiments, the non-oxygen etchant is a chlorine-containing plasma and the oxygen etchant is an oxygen-containing plasma. In some embodiments, the method further includes tuning parameters of the first etch step and the second etch step to control oxygen diffusion into the capping layer. The parameters may be tuned to limit an atomic ratio of oxygen in the capping layer to less than about 10%.

In some embodiments, the patterning layer formed over the absorber layer has a first thickness, and the selectively etching of the patterning layer includes switching from the first etch step to the second etch step when a thickness of the patterning layer is reduced by the first etch step from the first thickness to a second thickness. The second thickness is equal to a predetermined percentage of the first thickness of the patterning layer. In some embodiments, the predetermined percentage of the first thickness is less than or equal to 50%.

In some embodiments, the method further includes tuning parameters of the first etch step and the second etch step to control forming of an oxide layer over the absorber layer. The oxide layer may have a first portion disposed over a top of the absorber layer and a second portion disposed over sidewalls of the absorber layer. The parameters may be tuned to limit a first thickness of a tip of the second portion of the oxide layer disposed on the capping layer to less than 5% of a second thickness of the first portion of the oxide layer.

An exemplary extreme ultraviolet (EUV) mask includes a multilayer structure, a capping layer disposed over the multilayer structure, and a patterned absorber layer disposed over the capping layer. The patterned absorber layer has an opening therein that exposes a portion of the capping layer. The EUV mask further includes an oxide layer disposed over the patterned absorber layer. The oxide layer is disposed along sidewalls of the patterned absorber layer that form the opening therein. In some embodiments, an oxygen region is along a top of the exposed portion of the capping layer and an atomic ratio of oxygen in the oxygen region is less than about 10%. In some embodiments, the oxide layer disposed along the sidewalls of the patterned absorber layer extends to the capping layer. In such embodiments, a first thickness of a first portion of the oxide layer that physically contacts the capping layer may be less than 5% of a second thickness of a second portion of the oxide layer that is disposed on a top of the patterned absorber layer. In some embodiments, the oxide layer disposed along the sidewalls of the patterned absorber layer does not physically contact the capping layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
receiving an EUV mask having a multilayer structure, a capping layer disposed over the multilayer structure, a patterned absorber layer disposed over the capping layer, and a patterned hard mask disposed over the patterned absorber layer; and
removing the patterned hard mask by:
performing a first etching process to partially remove the patterned hard mask, wherein the first etching process uses a first etchant, and
performing a second etching process to remove a remainder of the patterned hard mask, wherein the second etching process uses a second etchant that is different than the first etchant.

2. The method of claim 1, wherein the first etchant is a halogen-based plasma, and the second etchant is a halogen-and-oxygen-based plasma.

3. The method of claim 2, wherein the halogen-based plasma is a Cl₂ plasma, and the halogen-and-oxygen-based plasma is a Cl₂+O₂ plasma.

4. The method of claim 1, further comprising performing the second etching process after the first etching process has reduced the patterned hard mask from a first thickness to a second thickness, wherein the second thickness is about 30% to about 50% of the first thickness.

5. The method of claim 1, wherein the first etching process removes the patterned hard mask at a first etch rate, the second etching process removes the patterned hard mask at a second etch rate, and the second etch rate is greater than the first etch rate.

6. The method of claim 1, wherein the patterned absorber layer exposes a portion of the capping layer, and the method further includes tuning parameters of the first etching process and the second etching process to control oxygen diffusion into the exposed portion of the capping layer, wherein an atomic ratio of oxygen in the exposed portion of the capping layer is limited to less than about 10%.

7. The method of claim 1, wherein an oxide layer is formed on the patterned absorber layer after the second etching process.

8. The method of claim 7, wherein the patterned absorber layer exposes a portion of the capping layer, and the method further includes tuning parameters of the second etching process to prevent formation of the oxide layer on the exposed portion of the capping layer.

9. The method of claim 7, wherein:
the oxide layer has a first portion disposed on a top of the patterned absorber layer and a second portion disposed on sidewalls of the patterned absorber layer;
the first portion of the oxide layer has a first thickness, the second portion of the oxide layer has a second thickness, and the second portion of the oxide layer has a tip having a third thickness that is less than the second thickness; and
the method further includes tuning parameters of the first etching process and the second etching process to limit the third thickness of the tip to less than 5% of the first thickness.

10. The method of claim 9, wherein:
the tip physically contacts a bottom corner of the patterned absorber layer; and
the third thickness is a minimum thickness of the oxide layer.

11. A method for fabricating an extreme ultraviolet (EUV) mask comprising:
forming a capping layer over a multilayer structure;
forming an absorber layer over the capping layer;
forming a patterning layer over the absorber layer;
selectively etching the absorber layer with respect to the capping layer using the patterning layer as an etch mask; and
selectively etching the patterning layer with respect to the capping layer and the absorber layer, wherein the selectively etching of the patterning layer includes a first etch step that uses a non-oxygen etchant to partially remove the patterning layer and a second etch step that uses an oxygen etchant to remove a remainder of the patterning layer.

12. The method of claim 11, wherein:
the non-oxygen etchant is a chlorine-containing plasma; and
the oxygen etchant is an oxygen-containing plasma.

13. The method of claim 11, wherein:
the patterning layer formed over the absorber layer has a first thickness; and
the selectively etching of the patterning layer includes switching from the first etch step to the second etch step when a thickness of the patterning layer is reduced by the first etch step from the first thickness to a second thickness, wherein the second thickness is equal to a predetermined percentage of the first thickness of the patterning layer.

14. The method of claim 13, wherein the predetermined percentage of the first thickness is less than or equal to 50%.

15. The method of claim 11, further comprising:
tuning parameters of the first etch step and the second etch step to control oxygen diffusion into the capping layer, wherein the parameters of the first etch step and the second etch step are tuned to limit an atomic ratio of oxygen in the capping layer to less than about 10%.

16. The method of claim 11, further comprising:
tuning parameters of the first etch step and the second etch step to control forming of an oxide layer over the absorber layer, wherein the oxide layer has a first portion disposed over a top of the absorber layer and a second portion disposed over sidewalls of the absorber layer; and
wherein the parameters of the first etch step and the second etch step are tuned to limit a first thickness of a tip of the second portion of the oxide layer disposed on the capping layer to less than 5% of a second thickness of the first portion of the oxide layer.

17. An extreme ultraviolet (EUV) mask comprising:
a multilayer structure;
a capping layer disposed over the multilayer structure;
a patterned absorber layer disposed over the capping layer, wherein the patterned absorber layer has an opening therein that exposes a portion of the capping layer; and
an oxide layer disposed over the patterned absorber layer, wherein the oxide layer is disposed along sidewalls of the patterned absorber layer that form the opening therein and the exposed portion of the capping layer is free of the oxide layer.

18. The EUV mask of claim 17, wherein:
an oxygen region is along a top of the exposed portion of the capping layer; and
an atomic ratio of oxygen in the oxygen region is less than about 10%.

19. The EUV mask of claim 17, wherein the oxide layer disposed along the sidewalls of the patterned absorber layer extends to the capping layer and a first thickness of a first portion of the oxide layer that physically contacts the capping layer is less than 5% of a second thickness of a second portion of the oxide layer that is disposed on a top of the patterned absorber layer.

20. The EUV mask of claim 17, wherein the oxide layer disposed along the sidewalls of the patterned absorber layer does not physically contact the capping layer.
